(19) United States
(12) Patent Application Publication
(10) Pub. No.: US 2012/0241754 A1
(43) Pub. Date: Sep. 27, 2012

(54) LIGHT EMITTING DIODE AND METHOD OF MANUFACTURING THEREOF

(75) Inventors: Ming-Teng Kuo, Taoyuan (TW); Jang-Ho Chen, Taoyuan (TW)

(73) Assignee: WALSIN LIHWA CORPORATION

(21) Appl. No.: 13/343,487

(22) Filed: Jan. 4, 2012

Related U.S. Application Data
(60) Provisional application No. 61/455,000, filed on Mar. 21, 2011.

(51) Int. Cl. H01L 33/20; H01L 33/32

(52) U.S. Cl. 257/76; 257/103; 438/44; 257/E33.006; 257/E33.023; 257/E33.044

(57) ABSTRACT

This invention directs to a light-emitting diode. The light-emitting diode includes a substrate, a semiconductor layer and an active layer. The semiconductor layer is disposed on the substrate and has a plurality of undulating structures. The active layer is conformably disposed on the semiconductor layer to have another plurality of undulating structures.

### RELATED APPLICATIONS

This application claims priority to U.S. Provisional Application Ser. No. 61/455,000, filed Mar. 21, 2011, which is herein incorporated by reference.

### BACKGROUND

1. Field of Invention

This invention relates to a device. More particularly, this invention relates to a device of a light-emitting diode.

2. Description of Related Art

Light-emitting diodes (LEDs) are a kind of semiconductor device. The advantages of light-emitting diodes are tiny, energy saving and long service life, which make them to be widely applied in various applications, such as indoor lighting, lamps, traffic signals, monitors, etc.

In the past few years, many studies have been focused on improving a luminous intensity of light-emitting diodes. However, the luminous intensity of light-emitting diodes still has a room to progress in comparing to conventional bulb. The studies of fabricating the light-emitting diodes with high luminous intensity are becoming a center concern in industrials. In general, the luminous intensity of light-emitting diodes depends on quantum efficiency, which refers to external quantum efficiency. The external quantum efficiency is a product of internal quantum efficiency multiply light extraction efficiency. The internal quantum efficiency is known as a photoelectric conversion efficiency, which mainly depends on characteristics of materials, such as band gap, quality of crystal lattice, such as defects or impurities, or epitaxial compositions and structures. The light extraction efficiency is the numbers of photons that can be measured from the external of the device, since photons generated by LED may be trapped inside due to internal absorption, refraction, and reflection. Although some studies have been done on the material of the light-emitting diode to improve the luminous intensity, little attention has been focused on epitaxial structures of the material itself and the light extraction efficiency.

Since epitaxial layers of the conventional light-emitting diode is prepared by continuous deposition process, a conventional multiple-quantum well layer of the light-emitting diode are formed in a flat structure, the luminous area is thus limited in the area the same as the substrate. Therefore, the luminous intensity of the conventional light-emitting diodes is not sufficient to satisfy application requirements.

### SUMMARY

Accordingly, in one aspect, this invention directs to a light-emitting diode. The light-emitting diode (LED) comprises a substrate, a semiconductor layer and an active layer. The semiconductor layer is disposed on the substrate and has a plurality of undulating structures. The active layer is conformably disposed on the semiconductor layer to have another plurality of undulating structures.

According to one embodiment of this invention, the semiconductor layer comprises an undoped layer and a first-type semiconductor layer disposed on the undoped layer.

According to another embodiment of this invention, the light-emitting diode further comprises a second-type semiconductor layer disposed on the active layer.

According to yet another embodiment of this invention, the first-type semiconductor layer is an N-type semiconductor layer, and the second-type semiconductor layer is a P-type semiconductor layer.

According to yet another embodiment of this invention, the N-type semiconductor layer is silicon doped gallium nitride layer, or silicon doped aluminum gallium indium phosphide layer.

According to yet another embodiment of this invention, the P-type semiconductor layer is magnesium doped gallium nitride layer, or magnesium doped aluminum gallium indium phosphide layer.

According to yet another embodiment of this invention, the undulating structures of the semiconductor layer are trenches having a width (L) not greater than 30 μm, a depth (D) not greater than 10 μm, and an L to D ratio not greater than 100.

According to yet another embodiment of this invention, the first-type semiconductor layer has a thickness (T) not greater than 10 μm, a T to D ratio not greater than 10, and a T to L ratio not greater than 10, when the trenches are in the undoped layer.

According to yet another embodiment of this invention, the active layer has a thickness (T) not greater than 10 μm, a T to D ratio not greater than 10, and a T to L ratio not greater than 10, when the trenches are in the firt-type semiconductor layer.

According to yet another embodiment of this invention, the LED further comprises another undoped layer directly disposed on the first-type semiconductor and having a thickness (T) not greater than 10 μm, a T to D ratio not greater than 10, and a T to L ratio not greater than 10, when the trenches are in the firt-type semiconductor layer.

In another aspect, this invention directs to a method of manufacturing a light-emitting diode. The method comprises steps hereinafter. A semiconductor layer is formed on a substrate. The semiconductor layer is then patterned to form a plurality of trenches in the semiconductor layer. An active layer is conformably formed on the semiconductor layer to have a plurality of undulating structures.

According to one embodiment of this invention, the method further comprises a step of forming a second-type semiconductor layer on the active layer.

According to another embodiment of this invention, the semiconductor layer comprises an undoped layer and a first-type semiconductor layer disposed on the undoped layer.

According to yet another embodiment of this invention, the trenches has a width (L) not greater than 30 μm, a depth (D) not greater than 10 μm, and an L to D ratio not greater than 100.

According to yet another embodiment of this invention, the first-type semiconductor layer has a thickness (T) not greater than 10 μm, a T to D ratio not greater than 10, and a T to L ratio not greater than 10, when the trenches are in the undoped layer.

According to yet another embodiment of this invention, the active layer has a thickness (T) not greater than 10 μm, a T to D ratio not greater than 10, and a T to L ratio not greater than 10, when the trenches are in the first-type semiconductor layer.

According to yet another embodiment of this invention, the method further comprises a step of forming another undoped layer directly on the first-type semiconductor layer to have a thickness (T) not greater than 10 μm, a T to D ratio not greater than 10, and a T to L ratio not greater than 10, when the trenches are in the first-type semiconductor layer.

Accordingly, the semiconductor layer of the LED in the embodiments of this invention has a plurality of undulating structure to make the active layer conformably disposed thereon to also have another plurality of undulating structures. Therefore, the insufficient luminous efficiency can be solved by increasing the luminous area of the active layer to increase the LED's luminous efficiency.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a cross-sectional view schematically illustrating a light-emitting diode according to one embodiment of this invention.

FIG. 2A is a cross-sectional view schematically illustrating a light-emitting diode according to another embodiment of this invention.

FIG. 2B is a cross-sectional view schematically illustrating a light-emitting diode according to yet another embodiment of this invention.

FIGS. 3A-3C are cross-sectional views schematically illustrating process steps for manufacturing a light-emitting diode according to one embodiment of this invention.

FIGS. 4A-4C are cross-sectional views schematically illustrating process steps for manufacturing a light-emitting diode according to another embodiment of this invention.

### DETAILED DESCRIPTION

Reference will now be made in detail to this embodiments of the invention, examples of which are illustrated in the accompanying drawings. Wherever possible, the same reference numbers are used in the drawings and the description to refer to the same or like parts.

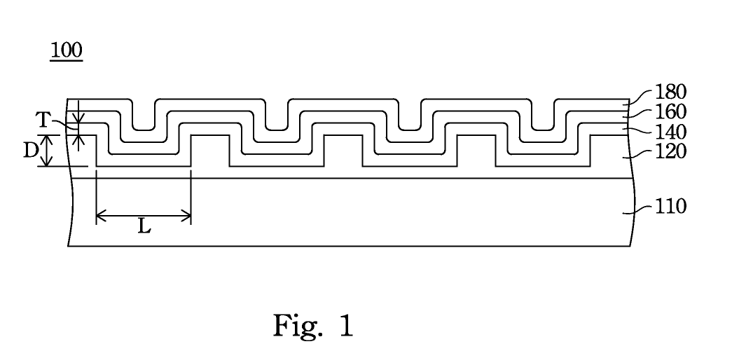

FIG. 1 is a cross-sectional view schematically illustrating a light-emitting diode 100 according to one embodiment of this invention. Referring to FIG. 1, the light-emitting diode 100 comprises a substrate 110, an undoped layer 120, a first-type semiconductor layer 140, an active layer 160 and a second-type semiconductor layer 180. The undoped layer 120 has a plurality of undulating structures. The first-type semiconductor layer 140 and the active layer 160 are conformably disposed on the undoped layer 120 to have another plurality of undulating structures.

The substrate 110 may be made of glass, quartz, sapphire, silicon carbide, gallium nitride (GaN), aluminum nitride, other suitable materials or combinations above.

The undoped layer 120 is used as a buffer layer. The undoped layer 120 may be made of a—group compound semiconductor or a II-VI group compound semiconductor. For example, the undoped layer 120 may be an undoped gallium nitride layer or an aluminum gallium indium phosphide layer. In one embodiment, the undoped layer 120 has a plurality of trenches. In another embodiment, the trenches of the undoped layer 120 has a width, L, equal to or less than 30 μm, the trenches of the undoped layer has a depth, D, equal to or less than 10 μm, and a L to D ratio is equal to or less than 100.

The first-type semiconductor layer 140 may be an N-type semiconductor layer made of the III-V group compound semiconductor or the II-VI group compound semiconductor. The method of forming the first-type semiconductor layer 140 may be epitaxial deposition, or molecular beam deposition, for example. The N-type semiconductor layer 140 may be a silicon doped gallium nitride layer, or a silicon doped aluminum gallium indium phosphide layer, for example. Since the undoped layer 120 has trenches, the first-type semiconductor layer 140 conformably disposed on the undoped layer 120 can also have undulating structures. In one embodiment, the first-type semiconductor layer 140 has a thickness, T, equal to or less than 10 μm, a T to D ratio equal to or less than 10, and a T to L ratio equal to or less than 10. In particular, the first-type semiconductor layer 140 may have a uniform thickness or a non-uniform thickness depending on the various application conditions.

The active layer 160 is a multiple quantum well (MQW) structure having alternately-stacked indium gallium nitride layers and gallium nitride layers. Since the first-type semiconductor layer 140 has the undulating structures, the active layer 160 conformably disposed on the first-type semiconductor layer 140 can also have undulating structures.

The second-type semiconductor layer 180 may be a P-type semiconductor layer made of the III-V group compound semiconductor or the II-VI group compound semiconductor. For example, the second-type semiconductor layer 180 may be a magnesium doped gallium nitride layer or a magnesium doped aluminum gallium indium phosphide layer. In one or more embodiments, the second-type semiconductor layer 180 may have undulating structures or a flat structure.

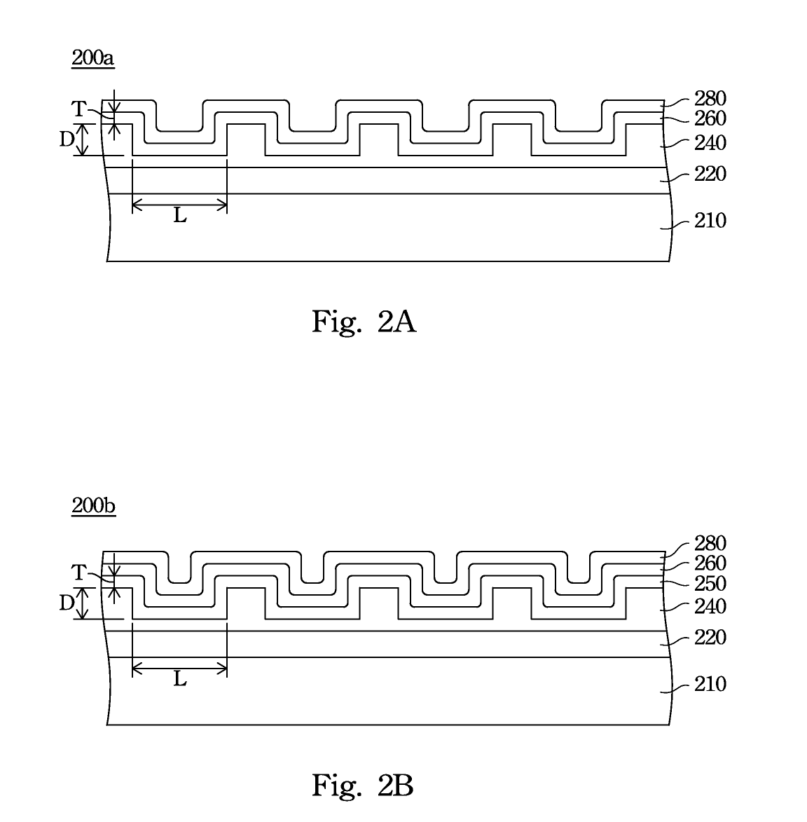

FIG. 2A is a cross-sectional view schematically illustrating a light-emitting diode 200a according to another embodiment of this invention. Referring to FIG. 2A, the light-emitting diode 200a comprises a substrate 210, an undoped layer 220, a first-type semiconductor layer 240, an active layer 260 and a second-type semiconductor layer 280. The first-type semiconductor layer 240 has undulating structures. The active layer 260 is conformably disposed on the first-type semiconductor layer 240 to also have undulating structures. The substrate 210 and the second-type semiconductor layer 280 depicted in FIG. 2 are the same as the substrate 110 and the second-type semiconductor layer 180 respectively depicted in FIG. 1, and thus the detail description of those elements are omitted herein.

The undoped layer 220 may be an epitaxial layer made of undoped gallium nitride. The first-type semiconductor layer 240 may be an N-type semiconductor layer made of the III-V group compound semiconductor, or the II-VI group compound semiconductor. For example, the first-type semiconductor layer 240 may be, but is not limited to, silicon doped gallium nitride layer, or silicon doped aluminum gallium indium phosphide layer.

According to an embodiment, the first-type semiconductor layer 240 has a plurality of trenches to form the undulating structures. In this embodiment, the trenches of the first-type semiconductor layer 240 has a width, L, equal to or less than 30 μm, and a depth, D, equal to or less than 10 μm, and a L to D ratio equal or less than 100

The active layer 260 is a multiple quantum well structure, which has indium gallium nitride layers and gallium nitride layers stacked alternately thereon. Since the first-type semiconductor layer 240 has the undulating structures, the active layer 260 conformably disposed on the first-type semiconductor layer 240 can also have undulating structures. In this embodiment, when the active layer 260 is directly disposed on the first-type semiconductor layer 240, the active layer 260 has a thickness, T, equal to or less than 10 μm, a T to D ratio equal to or less than 10, and a T to L ratio equal or less than 10.

FIG. 2B is a cross-sectional view schematically illustrating a light-emitting diode 200b according to other embodiment of this invention. Referring to FIG. 2B, a light-emitting diode 200b comprises the substrate 210, the undoped layer 220, the first-type semiconductor layer 240, a second undoped layer 250, the active layer 260 and the second-type semiconductor layer 280. Except from the second undoped layer 250, the rest elements depicted in FIG. 2B are the same as the elements depicted in FIG. 2A, thus the detail description of those elements are omitted herein.

The second undoped layer 250 may be made of the same material as the undoped layer 220. In this embodiment, the second undoped layer 250 is conformably disposed on the first-type semiconductor layer 240 to have an undulating structures as well. In other embodiment, a thickness of the second undoped layer 250 may be the same as the thickness T of the active layer 260 above.

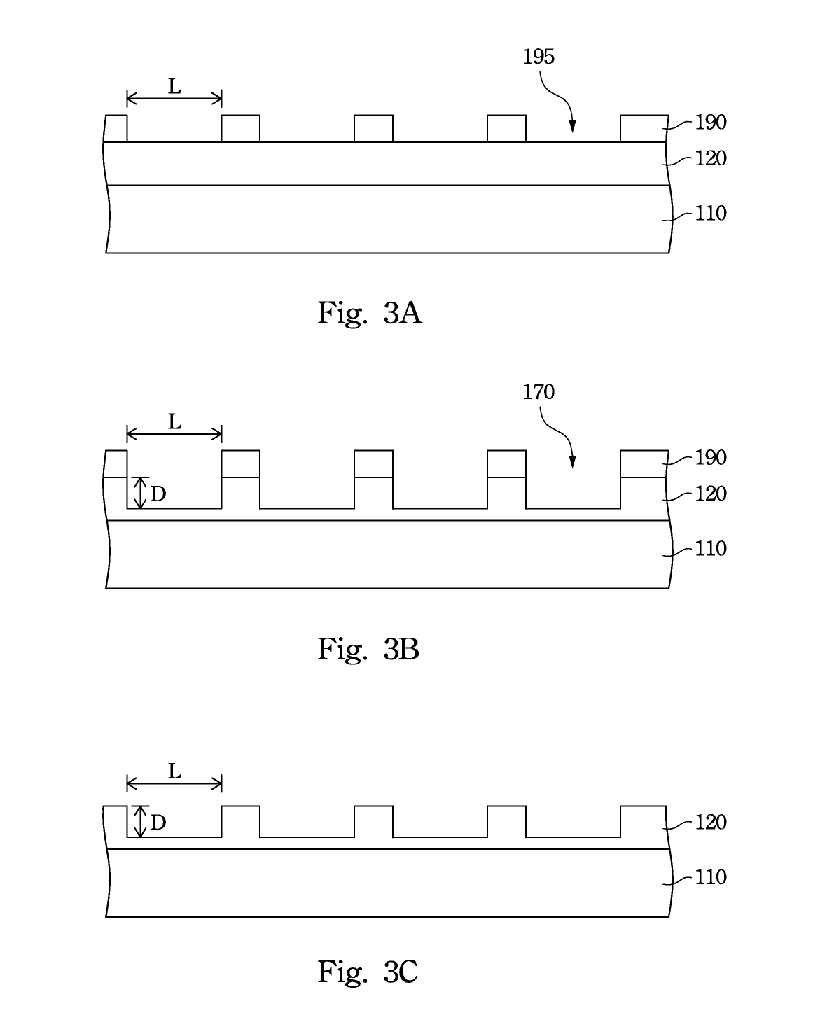

FIGS. 3A-3C are cross-sectional views schematically illustrating process steps for manufacturing the light-emitting diode 100 according to one embodiment of this invention. Referring to FIG. 3A, the undoped layer 120 and a photoresist layer 190 are sequentially formed on the substrate 110. The undoped layer 120 may be formed by a metal-organic chemical vapor deposition (MOCVD) process. The photoresist layer 190 may be formed by a spin coating process. Next, a photolithography process is performed on the photoresist layer 190, and a plurality of openings 195 are formed in the photoresist layer 190. In one embodiment, the openings 195 have a width, L.

Referring to FIG. 3B, the undoped layer 120 is etched to form a plurality of trenches 170. The etching process may be a dry etching or a wet etching. In particular, the dry etching may be an anisotropic etching process. In other embodiments, the trenches 170 may have a depth, D, equal to or less than 10 μm.

Referring to FIG. 3C, the photoresist layer 190 is removed. Next, the first-type semiconductor layer 140, the active layer 160 and the second-type semiconductor layer 180 may be sequentially formed on the undoped layer 120 to obtain the light-emitting diode 100 in FIG. 1. The first-type semiconductor layer 140, the active layer 160 and the second-type semiconductor layer 180 may be formed by the metal-organic chemical vapor deposition process. In other embodiments, the first-type semiconductor layer 140 may have a thickness, T, equal to or less than 10 μm. In particular, a T to D ratio is equal to or less than 10, and a T to L ratio is equal to or less than 10.

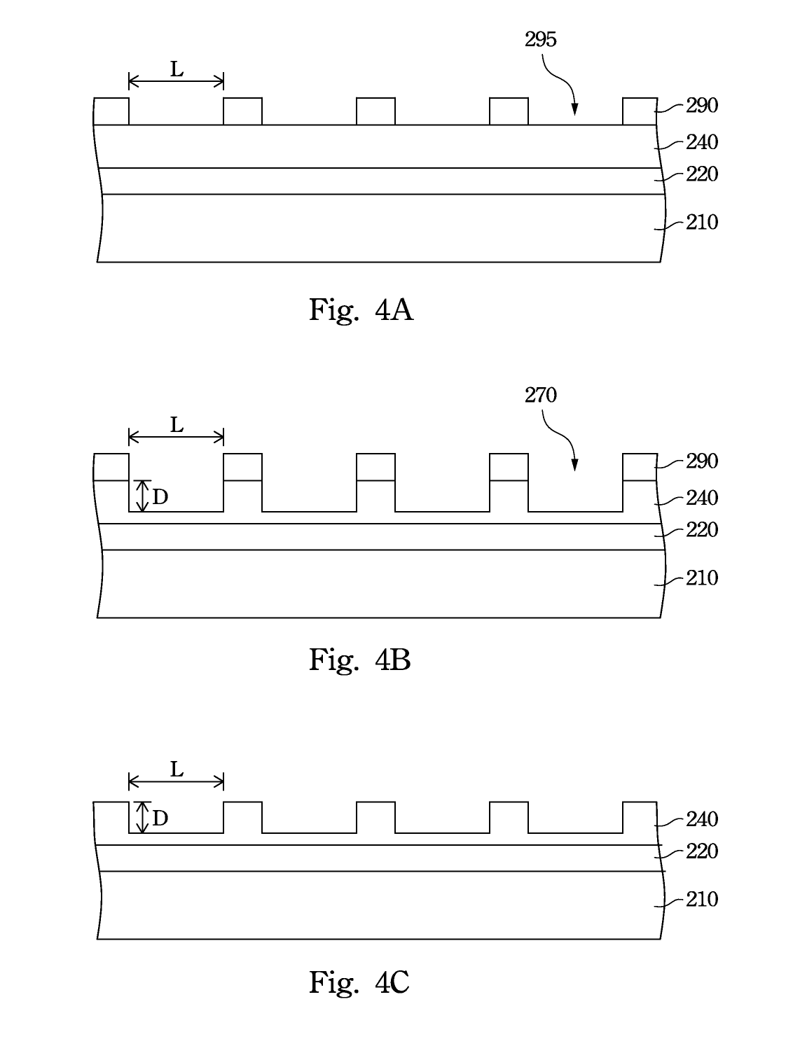

FIGS. 4A-4C are cross-sectional views schematically illustrating process steps for manufacturing a light-emitting diode 200a/200b according to another embodiment of this invention. Referring to FIG. 4A, the undoped layer 220, the first-type semiconductor layer 240 and a photoresist layer 290 are sequentially formed on the substrate 210. The undoped layer 220 and first-type semiconductor layer 240 are formed by a chemical vapor deposition process, such as metal-organic chemical vapor deposition. The photoresist layer 290 may be fabricated by the spin coating process. Next, a photolithography process is performed on the photoresist layer 290, and a plurality of openings 295 are formed on the photoresist layer 290. In one embodiment, the openings 295 have the width, L.

Referring to FIG. 4B, the first-type semiconductor layer 240 is etched to form a plurality of trenches 270 in the first-type semiconductor layer 240. The etching process may be dry etching or wet etching. In particular, the dry etching may be an anisotropic etching process. In one embodiment, the trenches 270 has a depth, D, equal to or less than 10 μm.

Referring to FIG. 4C, the photoresist layer 290 is removed. The active layer 260 and the second-type semiconductor layer 280 may be sequentially formed on the first-type semiconductor layer 240 to obtain the light-emitting diode 200a in FIG. 2A. The active layer 260 and the second-type semiconductor layer 280 may be formed by metal-organic chemical vapor deposition process. In other embodiment, when the active layer 260 is directly deposed on the first-type semiconductor layer 240, the active layer 260 may have a thickness, T, equal to or less than 10 μm, a T to D ratio equal to or less than 10, and a T to L ratio equal to or less than 10.

On the other hand, the above-mentioned etching process may cause the first-type semiconductor layer 240 having defects in its crystal lattice, which may further influence the subsequent crystal lattice of the active layer 260. In one or more embodiments, in order to have an integrity crystal lattice of the active layer 260, the light-emitting diode 200b may have the second undoped layer 250 disposed between the first-type semiconductor layer 240 and the active layer 260 to obtain the light-emitting diode 200b in FIG. 2B. In this embodiment, the second undoped layer 250 may conformably have the undulating structures. In one embodiment, when the second undoped layer 250 is directly disposed on the first-type semiconductor layer 240, the second undoped layer may have a thickness, T, equal to or less than 10 μm, a T to D ratio equal to or less than 10, and a T to L ratio equal to or less than 10.

As the description above, the light-emitting diode has the semiconductor layer with undulating structures, so that the active layer conformably disposed on the semiconductor layer can have undulating structures, too. As a result, the luminous efficiency of the light-emitting diode can be enhanced significantly by increasing the luminous area of the active layer, and thus the problem of insufficient luminous efficiency can be solved.

It will be apparent to those skilled in the art that various modifications and variations can be made to the structure of this invention without departing from the scope or spirit of the invention. In view of the foregoing, it is intended that this invention cover modifications and variations of this invention provided they fall within the scope of the following claims.

1. A light-emitting diode, comprising:
a substrate;
a semiconductor layer disposed on the substrate, wherein the semiconductor layer has a plurality of undulating structures; and
an active layer conformably disposed on the semiconductor layer to have another plurality of undulating structures.

2. The light-emitting diode of claim 1, wherein the semiconductor layer comprises an undoped layer and a first-type semiconductor layer disposed on the undoped layer.

3. The light-emitting diode of claim 2, further comprising a second-type semiconductor layer disposed on the active layer.

4. The light-emitting diode of claim 3, wherein the first-type semiconductor layer is an N-type semiconductor layer, and the second-type semiconductor layer is a P-type semiconductor layer.

5. The light-emitting diode of claim 4, wherein the N-type semiconductor layer is silicon doped gallium nitride layer, or silicon doped aluminum gallium indium phosphide layer.

6. The light-emitting diode of claim 4, wherein the P-type semiconductor layer is magnesium doped gallium nitride layer, or magnesium doped aluminum gallium indium phosphide layer.

7. The light-emitting diode of claim 2, wherein the undulating structures of the semiconductor layer are trenches.

8. The light-emitting diode of claim 7, wherein the trenches has a width (L) not greater than 30 μm, a depth (D) not greater than 10 μm, and an L to D ratio not greater than 100.

9. The light-emitting diode of claim 8, wherein the first-type semiconductor layer has a thickness (T) not greater than 10 μm, a T to D ratio not greater than 10, and a T to L ratio not greater than 10, when the trenches are in the undoped layer.

10. The light-emitting diode of claim 8, wherein the active layer has a thickness (T) not greater than 10 μm, a T to D ratio not greater than 10, and a T to L ratio not greater than 10, when the trenches are in the firt-type semiconductor layer.

11. The light-emitting diode of claim 8, further comprising another undoped layer directly disposed on the first-type semiconductor and having a thickness (T) not greater than 10 μm, a T to D ratio not greater than 10, and a T to L ratio not greater than 10, when the trenches are in the firt-type semiconductor layer.

12. A method of manufacturing a light-emitting diode, comprising:
forming a semiconductor layer on a substrate;
patterning the semiconductor layer to form a plurality of trenches in the semiconductor layer; and
conformably forming an active layer on the semiconductor layer so that the active layer has a plurality of undulating structures.

13. The method of claim 12, further comprising forming a second-type semiconductor layer on the active layer.

14-17. (canceled)

18. The method of claim 12, wherein the trenches has a width (L) not greater than 30 μm, a depth (D) not greater than 10 and an L to D ratio not greater than 100.

19. The method of claim 12, wherein the semiconductor layer comprises an undoped layer and a first-type semiconductor layer disposed on the undoped layer.

20. The method of claim 19, wherein the first-type semiconductor layer has a thickness (T) not greater than 10 μm, a T to D ratio not greater than 10, and a T to L ratio not greater than 10, when the trenches are in the undoped layer.

21. The method of claim 19, wherein the active layer has a thickness (T) not greater than 10 μm, a T to D ratio not greater than 10, and a T to L ratio not greater than 10, when the trenches are in the first-type semiconductor layer.

22. The method of claim 19, further comprising forming another undoped layer directly on the first-type semiconductor layer to have a thickness (T) not greater than 10 μm, a T to D ratio not greater than 10, and a T to L ratio not greater than 10, when the trenches are in the first-type semiconductor layer.
